(19) United States
(12) Patent Application Publication
(10) Pub. No.: US 2007/0152282 A1
(43) Pub. Date: Jul. 5, 2007

(54) Semiconductor Device and Fabrication Method Thereof

(76) Inventor: Jin Ha Park, Icheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/615,078

(22) Filed: Dec. 22, 2006

(30) Foreign Application Priority Data
Dec. 29, 2005 (KR) 10-2005-0133823

(51) Int. Cl. H01L 29/76

(52) U.S. Cl. 257/408

(57) ABSTRACT

A semiconductor device is provided. An embodiment of the semiconductor device includes: P-type source/drain regions formed in a semiconductor substrate; a gate insulation layer formed on a channel between the P-type source/drain regions; an N-type gate electrode formed on the gate insulation layer; and spacers with an ON structure formed on sidewalls of the gate insulation layer and the gate electrode, the spacers being made from an oxide layer and a nitride layer, wherein the nitride layer includes an implanted impurity. The implanted impurity in the nitride layer can cause compressive stress in the channel between the P-type source/drain regions.

### RELATED APPLICATION(S)

This application claims the benefit under 35 USC § 119(e) of Korean Patent Application No. 10-2005-0133823 filed Dec. 29, 2005, which is incorporated herein by reference in its entirety.

### FIELD OF THE INVENTION

The present invention relates to a semiconductor device and a fabrication method thereof, and more particularly to a semiconductor device that improves hole mobility in a PMOS device by inducing stress to a silicon channel, and a fabrication method thereof.

### BACKGROUND OF THE INVENTION

Generally, in a Complementary Metal Oxide Semiconductor (CMOS) transistor, a NMOS transistor and a PMOS transistor pair forms a specific circuit, e.g. a circuit such as an inverter or a flip-flop. One of the important indices representing the performance of a semiconductor device is carrier mobility of charges or holes. Entering the submicron generation, it becomes more difficult to maintain the carrier mobility of a device. Therefore, schemes capable of improving the hole mobility in a device, specifically, a PMOS device, have been continuously researched.

A technology incorporating an SiGe alloy has been proposed as a scheme for improving the hole mobility in PMOS devices. SiGe has a lattice constant greater than that of Si, and this lattice constant increases as the Ge concentration increases. Accordingly, when SiGe is epitaxially grown or deposited on a silicon substrate, the SiGe is formed to be compressive strained. Having a channel made from the compressive strained SiGe is very advantageous for carrier mobility for holes.

FIG. 1 is a sectional view of a PMOS device according to the prior art.

Referring to FIG. 1, a SiGe epilayer (not shown) is formed on a Si semiconductor substrate 100. For example, the SiGe epilayer may be formed by using Molecular Beam Epitaxy (MBE) or various types of Chemical Vapor Deposition (CVD) methods.

Then, in order to separate a NMOS device from a PMOS device, a Shallow Trench Isolation (STI) layer 101 is formed on the semiconductor substrate 100. An insulation layer and a polysilicon layer are sequentially deposited on the semiconductor substrate 100 and selectively etched to form a gate insulation layer 102 and a gate electrode 103.

Impurity ions are implanted at low concentration into source/drain regions to form source/drain regions 104.

Then, spacers 105 are formed on the sidewalls of the gate insulation layer 102 and the gate electrode 103. Subsequently, P-type impurity ions are implanted at high concentration into the SiGe epilayer using the gate electrode 103 and the spacers 10 as a mask, so that compressive strained epitaxial SiGe source/drain regions 106 are formed. Herein, the epitaxial SiGe source/drain regions 106 are grown in a temperature of about 500 to 600° C., and then refrigerated, so that the SiGe around a gate edge becomes increasingly compressive strained. Such additional compressive strain further improves the hole carrier mobility in a PMOS device.

The epitaxial SiGe source/drain regions 106 improves the hole carrier mobility in the PMOS device, but it is necessary to separately form the SiGe epilayer and then perform the process for implanting the impurity ions. Therefore, manufacturing cost inevitably increases and the process itself is very complicated. In addition, yield may deteriorate due to the use of the SiGe.

### SUMMARY OF THE INVENTION

Accordingly, embodiments of the present invention are directed to a semiconductor device and a fabrication method thereof that substantially obviates one or more problems due to limitations and disadvantages of the related art.

Accordingly, it is an object of embodiments of the present invention to provide a semiconductor device capable of improving the hole mobility in a PMOS device by inducing stress to a silicon channel while using existing semiconductor manufacturing processes without using a SiGe epilayer, and a fabrication method thereof.

It is another object of embodiments of the present invention to provide a semiconductor fabrication method in which the manufacturing cost can be reduced, existing semiconductor manufacturing processes can be used, and yield deterioration does not occur; and a semiconductor device fabricated using the semiconductor fabrication method.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

In accordance with one embodiment of the present invention, there is provided a semiconductor device including: a semiconductor substrate; source/drain regions formed in the semiconductor substrate; a gate insulation layer formed on a channel between the source/drain regions; a gate electrode formed on the gate insulation layer; and spacers with an ON structure formed on sidewalls of the gate insulation layer and the gate electrode, the spacers being made from an oxide layer and a nitride layer, wherein the nitride layer comprises an implanted impurity.

In accordance with another embodiment of the present invention, there is provided a semiconductor device including: a semiconductor substrate; source/drain regions formed in the semiconductor substrate; a gate insulation layer formed on a channel between the source/drain regions; a gate region formed on the gate insulation layer; and spacers formed on sidewalls of the gate insulation layer and the gate electrode, the spacers including at least a nitride layer, wherein an impurity capable of destroying the atomic binding of the SiN of the nitride layer is implanted into the nitride layer to apply a compressive stress to the channel, wherein the impurity has a high AMU (atomic mass unit).

In accordance with yet another embodiment of the present invention, there is provided a method for fabricating a semiconductor device, the method including: forming a gate insulation layer and a gate electrode on a semiconductor substrate; forming a low concentration impurity region for a Lightly Doped Drain (LDD) by implanting second conductive type impurity ions into the semiconductor substrate at low concentration using the gate electrode as a mask; forming an oxide layer on the semiconductor substrate including the gate electrode; forming a nitride layer on the oxide layer; implanting an impurity into the nitride layer; and forming spacers with an ON structure on sidewalls of the gate insulation layer and the gate electrode by performing an etchback process of the nitride layer and the oxide layer.

According to embodiments of the present invention, in a typical process forming spacers with an ON structure, since the hole carrier mobility in a PMOS device can be improved by simply implanting Ge into the nitride layer, process implementation can be easier as compared to technology using SiGe. Further, the hole carrier mobility in a PMOS device can be improved at a low cost as compared to the technology using SiGe.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a sectional view of a PMOS device according to the prior art; and

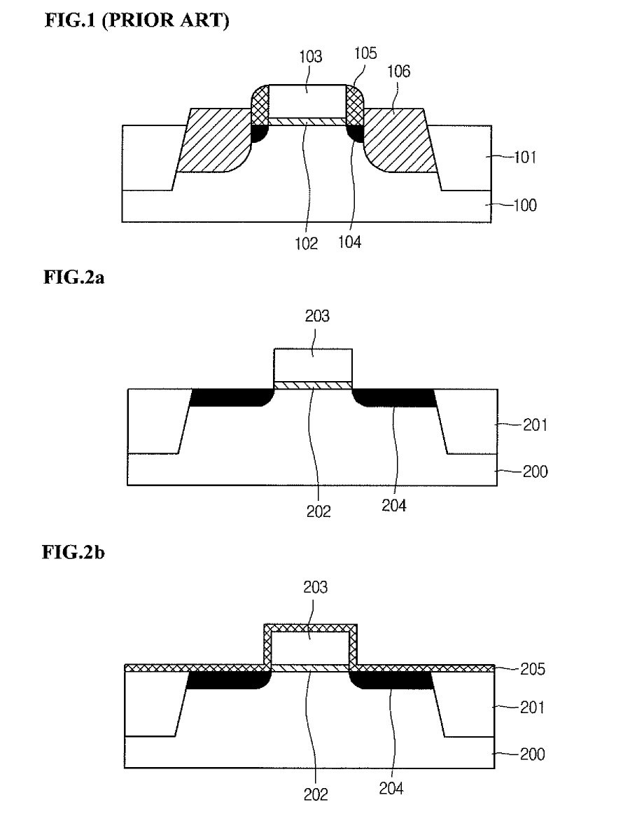

FIGS. 2a to 2e are sectional views illustrating a method for fabricating a PMOS device according to an embodiment of the present invention.

### DETAILED DESCRIPTION OF THE INVENTION

Hereinafter, a method for fabricating a semiconductor device according to an embodiment of the present invention will be described in more detail with reference to the accompanying drawings.

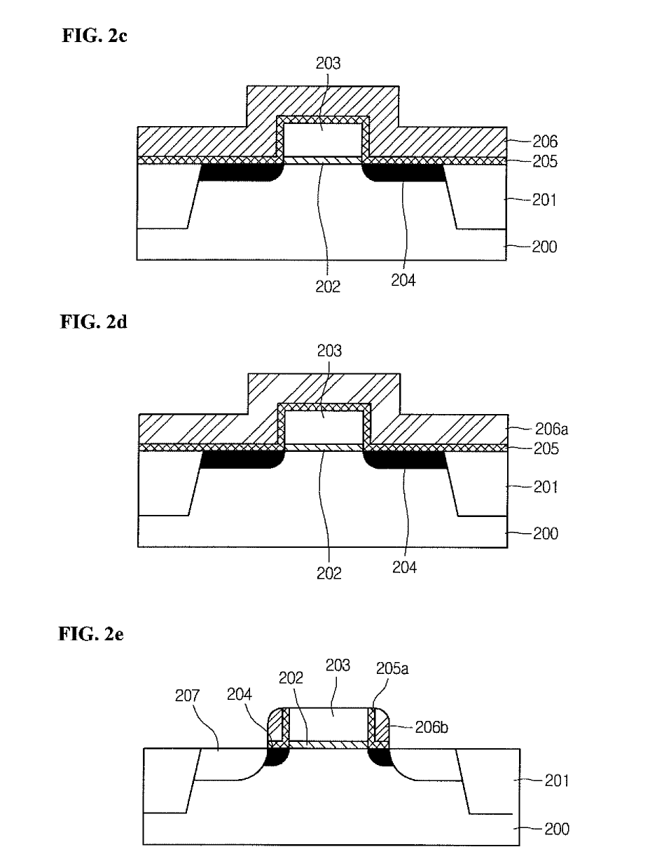

FIGS. 2a to 2e are sectional views illustrating a method for fabricating a semiconductor device based on an embodiment of the present invention.

Referring to FIG. 2a, a STI layer 201 can be formed on an N-type silicon semiconductor substrate 200 for separation from a NMOS device (not shown). An insulation layer and a polysilicon layer can be sequentially formed on the semiconductor substrate 200 and then selectively etched to form a gate insulation layer 202 and a gate electrode 203. In a specific embodiment, the polysilicon layer can be an N-type doped polysilicon layer.

Then, P-type impurity ions can be implanted at low concentration into the semiconductor substrate 200 using the gate electrode 203 as a mask to form a low concentration impurity region 204 for a Lightly Doped Drain (LDD). The low concentration impurity region 204 can be formed to prevent a transistor from abnormally operating in voltage smaller than threshold voltage as the channel length between source and drain becomes shorter due to reduction of a Critical Dimension (CD) of a gate electrode because of the high integration of a semiconductor device.

As shown in FIG. 2b, an oxide layer 205 can be formed on the entire surface of the semiconductor substrate 200 including the gate electrode 203. In an embodiment, the oxide layer 205 can be formed to have a thickness of 150 to 250 Å. In a preferred embodiment, the oxide layer 205 can have a thickness of about 200 Å. When the oxide layer 205 has a thickness less than 150 Å, an ion implantation of a nitride layer formed in a subsequent process may affect the silicon channel. When the oxide layer 205 has a thickness exceeding 250 Å, the stress of the nitride layer according to the ion implantation may not be sufficiently transferred to the silicon channel. In a preferred embodiment, the oxide layer can be made from Tetraethoxysilane.

As shown in FIG. 2c, a nitride layer 206 can be formed on the oxide layer 205. The nitride layer 206 can be formed to have a thickness of 650 to 750 Å. In a preferred embodiment, the nitride layer 206 can have a thickness of about 700 Å. When the nitride layer 206 has a thickness less than 650 Å, it may have influence on a silicon channel in a subsequent impurity implantation process. When the nitride layer 206 has a thickness exceeding 750 Å, the compression stress applied to the silicon channel becomes small.

Referring to FIG. 2d, impurity ions can be implanted into the nitride layer 206. In a preferred embodiment, Ge can be implanted into the nitride layer 206 so that the nitride layer 206 is transformed into a nitride layer 206a having Ge. Because the atomic binding of the nitride layer is minimally and partially destroyed due to the implantation of Ge, stress occurs. As a result, compressive stress is formed in the silicon channel. The compressive stress in the silicon channel significantly improves the hole carrier mobility in a PMOS device.

In one embodiment, Ge can be implanted at a dose of about 5×10¹⁴ ion/cm² using an ion implantation energy of about 40 to 100 KeV. In a preferred embodiment, the ion implantation can be 80 KeV. When the ion implantation energy is less than 40 KeV, a required stress change does not occur. When the ion implantation energy exceeds 100 KeV, it should be noted that it may have a bad influence on the substrate 200.

In the meantime, the implanted impurity can destroy the atomic binding of SiN in the nitride layer 206. Any impurity having a large Atomic Mass Unit (AMU) can be used. In a preferred embodiment, since ions with a valence of 3 or 5 may function as an N-type or P-type dopant for a substrate, Ge with a valence of 4 or an inert gas such as Ar gas can be used.

Referring to FIG. 2e, the nitride layer 206a having the implanted Ge and the oxide layer 205 can be selectively etched to form spacers 205a and 206b with an ON structure the sidewalls of the gate insulation layer 202 and the gate electrode 203. The ON structure denotes a structure in which an oxide/SiN layer is formed.

P-type impurity ions can be implanted at high concentration into the semiconductor substrate 200 using the gate electrode 203 and the spacers 205a and 206b as a mask to form source/drain regions 207.

As a result, FIG. 2e shows a semiconductor device according to an embodiment of the present invention. In one embodiment, the semiconductor device includes the low concentration impurity region 204 for LDD, the P-type source/drain regions 207, the gate insulation layer 202, and an N-type gate electrode 203 on the substrate 200. In addition, the spacers 205a and 206b with the ON structure are provided on the sidewalls of the gate insulation layer 202 and the gate electrode 203.

Herein, since an impurity (e.g. Ge) destroying the atomic binding of SiN has been implanted into the nitride layer in the spacers, compressive stress occurs due to the nitride layer. Therefore, compressive stress also occurs in the channel on the substrate. The compressive stress in the channel improves the hole mobility.

According to embodiments of the present invention, the following effects can be obtained.

First, in a typical process forming the spacers with an ON structure, since the hole carrier mobility in a PMOS device can be improved by simply implanting Ge into the nitride layer, process implementation is easier as compared to technology using SiGe. Second, the hole carrier mobility in a PMOS device can be improved at a low cost compared with the technology using SiGe. Lastly, there is no yield deterioration problem as occurring when using SiGe.

The present invention is not limited the above-described embodiments, and may include other embodiments having the equivalent scope.

For example, the oxide layer 205 functions as a buffer layer, and the nitride layer 206 can be used to increase carrier concentration for a semiconductor device without forming the oxide layer 205. Although not providing the oxide layer 205 is not the preferred embodiment because stress due to the nitride layer 206 may have influence on the gate electrode 203, this influence is not necessarily a bad influence on implementing the scope of the present invention. Further, since the oxide layer is generally applied to protect layers below the oxide layer, it can be easily applied without disadvantages in processes, increases in cost, etc.

It will be apparent to those skilled in the art that various modifications and variations can be made in the present invention. Thus, it is intended that the present invention covers the modifications and variations of this invention provided they come within the scope of the appended claims and their equivalents.

I claim:

1. A semiconductor device comprising:
a semiconductor substrate;
source/drain regions of a second conductive type formed in the semiconductor substrate;
a gate insulation layer formed on a channel between the source/drain regions;
a gate electrode having implanted first conductive type impurities formed on the gate insulation layer; and
spacers with an ON structure formed on sidewalls of the gate insulation layer and the gate electrode, the spacers being formed from an oxide layer and a nitride layer, wherein the nitride layer comprises an implanted impurity.

2. The semiconductor device according to claim 1, wherein an that atomic binding of the nitride layer is destroyed by the implanted impurity.

3. The semiconductor device according to claim 1, wherein the implanted impurity comprises Ge or Ar.

4. The semiconductor device according to claim 1, wherein the first conductive type is N-type and the second conductive type is P-type.

5. The semiconductor device according to claim 1, wherein the oxide layer has a thickness of 150 Å to 250 Å.

6. The semiconductor device according to claim 1, wherein the nitride layer has a thickness of 650 Å to 750 Å.

7. The semiconductor device according to claim 1, wherein the oxide layer has a thickness of 200 Å and the nitride layer has a thickness of 700 Å.

8. A semiconductor device comprising:
a semiconductor substrate;
source/drain regions formed in the semiconductor substrate;
a gate insulation layer formed on a channel between the source/drain regions;
a gate electrode formed on the gate insulation layer; and
spacers formed on sidewalls of the gate insulation layer and the gate electrode, the spacers comprising a nitride layer,
wherein an impurity capable of destroying atomic binding of SiN in the nitride layer is implanted into the nitride layer for applying compressive stress to the channel between the source/drain regions, wherein the impurity has a high AMU (atomic mass unit).

9. The semiconductor device according to claim 8, wherein the impurity comprises an element having a valence of 4 or an inert gas.

10. The semiconductor device according to claim 8, wherein the impurity comprises Ge or Ar.

11. The semiconductor device according to claim 8, wherein the spacers further comprise a buffer layer interposed between the nitride layer and the gate electrode.

12. The semiconductor device according to claim 11, wherein the buffer layer comprises an oxide layer.

13. A method for fabricating a semiconductor device, the method comprising:
forming a gate insulation layer and a gate electrode having implanted first conductive type impurities on a semiconductor substrate;
forming a low concentration impurity region for a Lightly Doped Drain (LDD) by implanting second conductive type impurity ions into the semiconductor substrate at low concentration using the gate electrode as a mask;
forming an oxide layer on the semiconductor substrate having the gate electrode;
forming a nitride layer on the oxide layer;
implanting impurity into the nitride layer; and
forming spacers with an ON structure on sidewalls of the gate insulation layer and the gate electrode by performing an etchback process of the nitride layer and the oxide layer.

14. The method according to claim 13, wherein implanting the impurity into the nitride layer comprises implanting impurity ions at a dose and implantation energy so that atomic binding of the nitride layer is minimally and partially destroyed.

15. The method according to claim 13, wherein the impurity comprises Ge or Ar.

16. The method according to claim 13, wherein the first conductive type is N-type and the second conductive type is P-type.

17. The method according to claim 13, wherein the oxide layer has a thickness of 150 Å to 250 Å and the nitride layer has a thickness of 650 Å to 750 Å.

18. The method according to claim 13, wherein the oxide layer has a thickness of 200 Å and the nitride layer has a thickness of 700 Å.

19. The method according to claim 13, wherein the impurity is implanted at a dose of about 5×10¹⁴ ion/cm² using an ion implantation energy of about 40 to 100 KeV.

20. The method according to claim 13, wherein the impurity is implanted using an ion implantation energy of about 40 to 100 KeV.
